(19) United States
(12) Patent Application Publication
(10) Pub. No.: US 2025/0253610 A1
(43) Pub. Date: Aug. 7, 2025

(54) EPITAXIAL LAYER STRUCTURE FOR ISOLATION OF ELECTRONIC CIRCUIT DEVICES ON DOPED SUBSTRATE

(71) Applicant: Soreq Nuclear Research Center, Yavne (IL)

(72) Inventors: Doron Cohen-Elias, Yavne (IL); Rimon Tamari, Yavne (IL); David Memram, Yavne (IL)

(73) Assignee: Soreq Nuclear Research Center, Yavne (IL)

(21) Appl. No.: 19/117,095

(22) PCT Filed: Sep. 3, 2023
(86) PCT No.: PCT/IB2023/058709

§ 371 Date: Mar. 31, 2025

Related U.S. Application Data
(60) Provisional application No. 63/403,792, filed on Sep. 5, 2022.

(51) Int. Cl. H01S 5/023; H01S 5/02; H01S 5/42

(52) U.S. Cl. CPC H01S 5/023; H01S 5/0206; H01S 5/423

(57) ABSTRACT

A semiconductor device includes a doped gallium arsenide (GaAs) substrate, and buffer columns grown or deposited on the doped GaAs substrate. Each of the buffer columns includes NIPI (n-type/intrinsic/p-type/intrinsic) or NIPIN (n-type/intrinsic/p-type/intrinsic/n-type) layers. An isolation trench is etched between two adjacent buffer columns of the buffer columns. and electronic circuit elements and contacts are placed on the buffer layers.

### FIELD OF THE INVENTION

The present invention relates generally to isolation between two semiconductor devices, and particularly to an epitaxial layer structure for isolation of electronic circuit devices on a doped substrate.

### BACKGROUND OF THE INVENTION

Isolation between two semiconductor devices is crucial for eliminating cross talks and breakdowns, which are common challenges in addressable matrix of detectors or high power vertical cavity surface emitting lasers (VCSEL).

An undoped gallium arsenide (GaAs) substrate is a common solution for device isolation, however undoped GaAs substrates are known for their high etch pit density (EPD) which degrades the device performance. Doped GaAs substrates have low EPD but also have low resistance, which is not suitable for isolation.

### SUMMARY

The present invention seeks to provide an epitaxial layer structure for isolation of electronic circuit devices on a doped substrate, as is described hereinbelow. The invention is particularly useful for isolation of high power addressable VCSEL matrix on a doped substrate,

In one embodiment, the semiconductor device includes a doped gallium arsenide (GaAs) substrate, buffer columns grown or deposited on the doped GaAs substrate, each of the buffer columns including NIPI (n-type/intrinsic/p-type/intrinsic) or NIPIN (n-type/intrinsic/p-type/intrinsic/n-type) layers, an isolation trench etched between two adjacent buffer columns of the buffer columns, and electronic circuit elements and contacts placed on the buffer layers.

### BRIEF DESCRIPTION OF THE DRAWINGS

The present invention will be understood and appreciated more fully from the following detailed description taken in conjunction with the drawings in which:

FIG. 1 is a simplified schematic illustration of devices isolated with buffer layers grown on a doped GaAs substrate, in accordance with an embodiment of the invention.

FIG. 2 is a simplified graphic illustration of the IV characteristic between two NIPI devices, with breakdown voltage above 45 Volt.

### DETAILED DESCRIPTION

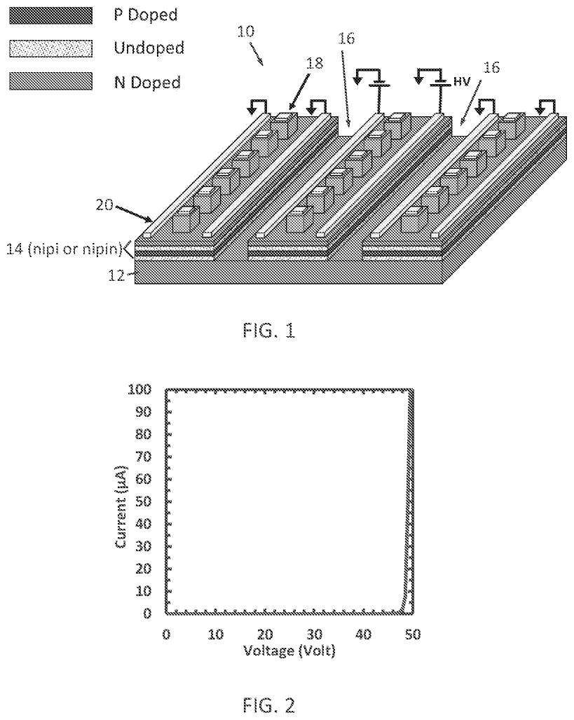

Reference is now made to FIG. 1, which illustrates a semiconductor device 10, in accordance with an embodiment of the invention.

The device includes a doped GaAs substrate 12 (examples of doping are provide below). Two or more buffer layers 14 (also called buffer columns 14) are grown or deposited on the doped GaAs substrate 12. Each buffer layer 14 may include NIPI (n-type/intrinsic/p-type/intrinsic) or NIPIN (n-type/intrinsic/p-type/intrinsic/n-type) layers. A trench 16 is etched between two adjacent buffer layers (columns) 14 for isolation. In this configuration, when high voltage is applied between two columns, two PIN diodes formed by the NIPI layers or NIPIN layers are reverse-biased and block the current up to the breakdown voltage.

Electronic circuit elements 18 and contacts 20 are placed on each buffer layer 14. In one embodiment, the circuit elements 18 are high power vertical cavity surface emitting lasers.

In FIG. 2, IV characteristic of two NIPI devices is shown. The layers were grown on GaAs Si doped substrate, the undoped layers were 700 nm thick with ˜5×10¹⁵ cm⁻³ unintentionally P type doping. The P and N layers had ˜3-4 10¹⁸ cm⁻³ carbon and silicon doping respectively, and the devices area was 800×800 μm².

What is claimed is:

1. A semiconductor device comprising:
a doped gallium arsenide (GaAs) substrate;
buffer columns grown or deposited on said doped GaAs substrate, each of said buffer columns comprising NIPI (n-type/intrinsic/p-type/intrinsic) or NIPIN (n-type/intrinsic/p-type/intrinsic/n-type) layers;
an isolation trench etched between two adjacent buffer columns of said buffer columns; and
electronic circuit elements and contacts placed on said buffer layers.

2. The semiconductor device according to claim 1, wherein when high voltage is applied between the two adjacent buffer columns, two PIN diodes formed by the NIPI or NIPIN layers are reverse-biased and block current up to a breakdown voltage.

3. The semiconductor device according to claim 1, wherein said electronic circuit elements comprise high power vertical cavity surface emitting lasers.
